(19) United States
(12) Patent Application Publication
(10) Pub. No.: US 2016/0358749 A1
(43) Pub. Date: Dec. 8, 2016

(54) PLASMA ETCHING DEVICE WITH PLASMA ETCH RESISTANT COATING

(71) Applicant: Lam Research Corporation, Fremont, CA (US)

(72) Inventor: Sanket Sant, Fremont, CA (US)

(21) Appl. No.: 15/158,397

(22) Filed: May 18, 2016

Related U.S. Application Data
(60) Provisional application No. 62/170,977, filed on Jun. 4, 2015.

(51) Int. Cl. H01J 37/32; C23C 16/505; C23C 16/455; C23C 14/22

(52) U.S. Cl. CPC H01J 37/3211; C23C 14/22; C23C 16/505; C23C 16/45525; H01J 37/32532; H01J 37/3244; H01J 2237/334; H01J 2237/3321

(57) ABSTRACT

An apparatus for processing a substrate is provided. A chamber wall forms a processing chamber cavity. A substrate support for supporting the substrate is within the processing chamber cavity. A gas inlet for providing gas into the processing chamber is above a surface of the substrate. A window for passing RF power into the processing chamber cavity comprises a ceramic or quartz window body and a coating of at least one of erbium oxide, erbium fluoride, samarium oxide, samarium fluoride, thulium oxide thulium fluoride, gadolinium oxide, or gadolinium fluoride on a surface of the ceramic window body. A coil is outside of the processing chamber cavity, wherein the window is between the processing chamber cavity and the coil.

### BACKGROUND

The present disclosure relates to the manufacturing of semiconductor devices. More specifically, the disclosure relates to coating chamber surfaces used in manufacturing semiconductor devices.

During semiconductor wafer processing, plasma processing chambers are used to process semiconductor devices. Coatings are used to protect and ensure successful performance of the chamber surfaces in manufacturing semiconductor devices.

Descriptions and embodiments discussed in this background are not presumed to be prior art. Such descriptions are not an admission of prior art.

### SUMMARY

To achieve the foregoing and in accordance with the purpose of the present disclosure, an apparatus for processing a substrate is provided. A chamber wall forms a processing chamber cavity. A substrate support for supporting the substrate is within the processing chamber cavity. A gas inlet for providing gas into the processing chamber is above a surface of the substrate. A window for passing RF power into the processing chamber cavity comprises a ceramic or quartz window body and a coating of at least one of erbium oxide, erbium fluoride, samarium oxide, samarium fluoride, thulium oxide thulium fluoride, gadolinium oxide, or gadolinium fluoride on a surface of the ceramic window body. A coil is outside of the processing chamber cavity, wherein the window is between the processing chamber cavity and the coil.

In another manifestation, an apparatus for plasma processing a substrate is provided. A chamber wall forms a processing chamber cavity. A substrate support for supporting the substrate is within the processing chamber cavity. A gas inlet for provides a gas into the processing chamber cavity. At least one plasma electrode is provided for transforming a gas within the processing chamber cavity into a plasma. A coating comprising at least one of erbium oxide, erbium fluoride, samarium oxide, samarium fluoride, thulium oxide thulium fluoride, gadolinium oxide, or gadolinium fluoride is on a surface within the processing chamber cavity, wherein the coating is 1 to 50 microns thick.

In another manifestation of the disclosure an apparatus for use in a plasma etch chamber is provided. The apparatus comprises a ceramic, stainless steel, or quartz body and a coating comprising at least one of erbium oxide, erbium fluoride, samarium oxide, samarium fluoride, thulium oxide thulium fluoride, gadolinium oxide, or gadolinium fluoride covering a surface of the ceramic body, wherein the coating is 1 to 50 microns thick.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic view of an etch reactor that may be used in an embodiment.

FIG. 2 is an enlarged cross-sectional view of part of a liner.

FIG. 3 is an enlarged cross-sectional view of an electrostatic chuck which forms a lower electrode.

FIG. 4 schematically illustrates an example of another plasma processing chamber.

FIG. 5 is an enlarged cross-sectional view of a power window.

FIG. 6 is an enlarged cross-sectional view of the gas injector.

FIG. 7 is an enlarged cross-sectional view of part of a edge ring.

FIG. 8 is an enlarged cross-sectional view of part of a pinnacle.

### DETAILED DESCRIPTION OF THE EMBODIMENTS

The present disclosure will now be described in detail with reference to a few embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

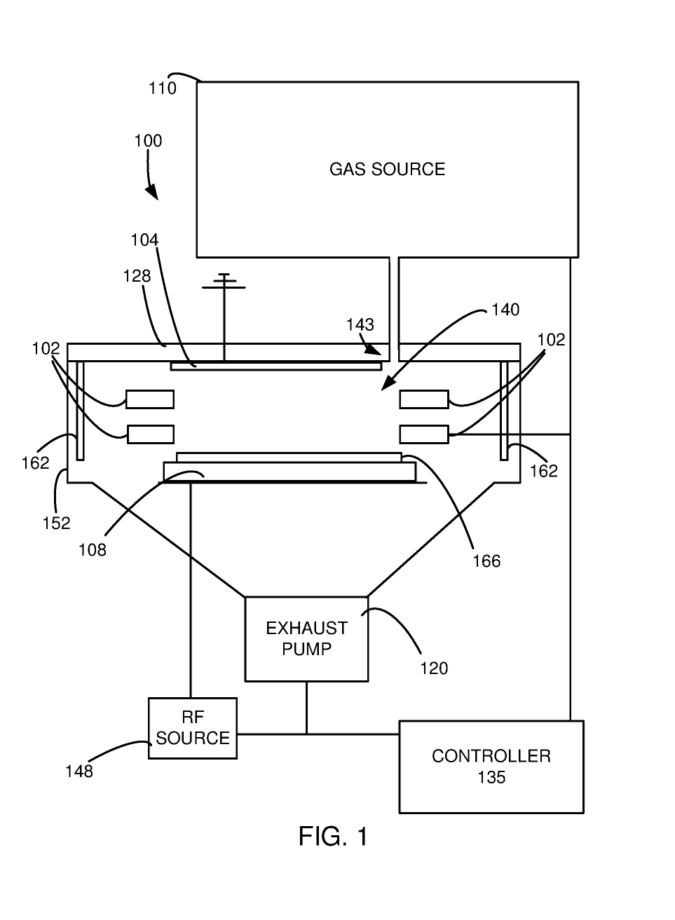

To facilitate understanding, FIG. 1 is a schematic view of a plasma processing chamber 100 in which a substrate 166 has been mounted. The plasma processing chamber 100 comprises confinement rings 102, an upper electrode 104, a lower electrode 108, a gas source 110, a liner 162, and an exhaust pump 120. The liner 162 is formed from the substrate with the remelted ceramic layer. Within plasma processing chamber 100, the wafer 166 is positioned upon the lower electrode 108. The lower electrode 108 incorporates a suitable substrate chucking mechanism (e.g., electrostatic, mechanical clamping, or the like) for holding the wafer 166. The reactor top 128 incorporates the upper electrode 104 disposed immediately opposite the lower electrode 108. The upper electrode 104, lower electrode 108, and confinement rings 102 define the confined plasma volume 140.

Gas is supplied to the confined plasma volume 140 through a gas inlet 143 by the gas source 110 and is exhausted from the confined plasma volume 140 through the confinement rings 102 and an exhaust port by the exhaust pump 120. Besides helping to exhaust the gas, the exhaust pump 120 helps to regulate pressure. A RF source 148 is electrically connected to the lower electrode 108.

Chamber walls 152 surround the liner 162, confinement rings 102, the upper electrode 104, and the lower electrode 108. The liner 162 helps prevent gas or plasma that passes through the confinement rings 102 from contacting the chamber walls 152. Different combinations of connecting RF power to the electrode are possible. In an embodiment, the 27 MHz, 60 MHz and 2 MHz power sources make up the RF power source 148 connected to the lower electrode 108, and the upper electrode 104 is grounded. A controller 135 is controllably connected to the RF source 148, exhaust pump 120, and the gas source 110. The process chamber 100 may be a CCP (capacitive coupled plasma) reactor or an ICP (inductive coupled plasma) reactor or other sources like surface wave, microwave, or electron cyclotron resonance ECR may be used.

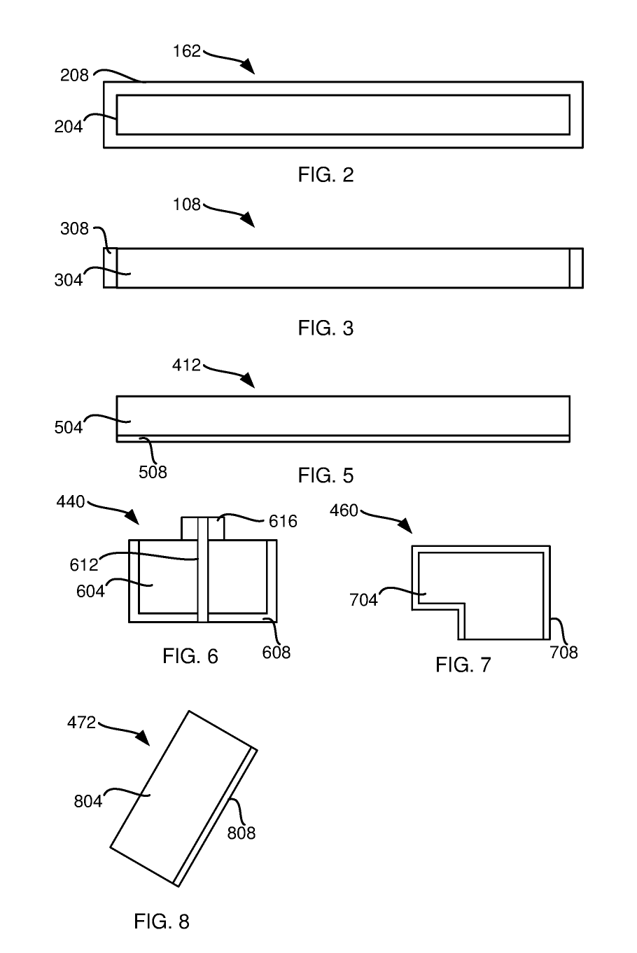

FIG. 2 is an enlarged cross-sectional view of part of the liner 162. The liner 162 comprises a liner body 204 and a coating 208 covering at least one surface of the liner body 204. The liner body 204 may be of one or more different materials. Preferably, the liner body 204 is ceramic, quartz, or stainless steel. More preferably, the liner body 204 comprises at least one of stainless steel, silicon (Si), quartz, silicon carbide (SiC), silicon nitride (SiN), aluminum oxide (AlO), aluminum nitride (AlC), or aluminum carbide (AlC). Preferably, the liner body 204 is aluminum oxide. The coating 208 comprises at least one of erbium oxide, erbium fluoride, samarium oxide, samarium fluoride, thulium oxide thulium fluoride, gadolinium oxide, or gadolinium fluoride. Therefore, the coating may be a one or more in combination of erbium oxide, erbium fluoride, samarium oxide, samarium fluoride, thulium oxide thulium fluoride, gadolinium oxide, or gadolinium fluoride and may also have other materials. Such other materials may be impurities which are difficult to remove in obtaining erbium oxide, erbium fluoride, samarium oxide, samarium fluoride, thulium oxide thulium fluoride, gadolinium oxide, or gadolinium fluoride or may be binding agents to allow the binding of the coating to the liner body. More preferably, the coating is >60% pure by weight of at least one of erbium oxide, erbium fluoride, samarium oxide, samarium fluoride, thulium oxide thulium fluoride, gadolinium oxide, or gadolinium fluoride. Most preferably, the coating is >99% pure by weight of at least one of erbium oxide, erbium fluoride, samarium oxide, samarium fluoride, thulium oxide thulium fluoride, gadolinium oxide, or gadolinium fluoride. Preferably, the coating is 1-50 μ thick. More preferably, the coating is 5-20 μ thick. Most preferably, the coating is 8-15 μ thick. To provide such a uniform and thin coating, preferably the coating is formed by at least one of plasma-enhanced chemical vapor deposition (PECVD), physical vapor deposition (PVD), chemical vapor deposition (CVD), atomic layer deposition (ALD), or aerosol deposition (ASD). More preferably, the coating is formed by PECVD or PVD.

FIG. 3 is an enlarged cross-sectional view of the electrostatic chuck which forms the lower electrode 108. The lower electrode 108 comprises a lower electrode body 304 and a coating 308 covering at least one surface of the lower electrode body 304. In this example, the coating 308 is only on the side surface of the lower electrode body 304. The lower body 304 may be of one or more different materials. Preferably, the lower electrode body 304 is ceramic, quartz, or stainless steel. More preferably, the lower electrode body 304 comprises at least one of stainless steel, silicon (Si), quartz, silicon carbide (SiC), silicon nitride (SiN), aluminum oxide (AlO), aluminum nitride (AlC), or aluminum carbide (AlC). The coating 308 comprises at least one of erbium oxide, erbium fluoride, samarium oxide, samarium fluoride, thulium oxide thulium fluoride, gadolinium oxide, or gadolinium fluoride. Therefore, the coating may be a one or more in combination of erbium oxide, erbium fluoride, samarium oxide, samarium fluoride, thulium oxide thulium fluoride, gadolinium oxide, or gadolinium fluoride and may also have other materials. Such other materials may be impurities which are difficult to remove in obtaining erbium oxide, erbium fluoride, samarium oxide, samarium fluoride, thulium oxide thulium fluoride, gadolinium oxide, or gadolinium fluoride or may be binding agents to allow the binding of the coating to the electrode body. More preferably, the coating is >60% pure by weight of at least one of erbium oxide, erbium fluoride, samarium oxide, samarium fluoride, thulium oxide thulium fluoride, gadolinium oxide, or gadolinium fluoride. Most preferably, the coating is >99% pure by weight of at least one of erbium oxide, erbium fluoride, samarium oxide, samarium fluoride, thulium oxide thulium fluoride, gadolinium oxide, or gadolinium fluoride. Preferably, the coating is 1-50 μ thick. More preferably, the coating is 5-20 μ thick. Most preferably, the coating is 8-15 μ thick. To provide such a uniform and thin coating, preferably the coating is formed by at least one of plasma-enhanced chemical vapor deposition (PECVD), physical vapor deposition (PVD), chemical vapor deposition (CVD), atomic layer deposition (ALD), or aerosol deposition (ASD).

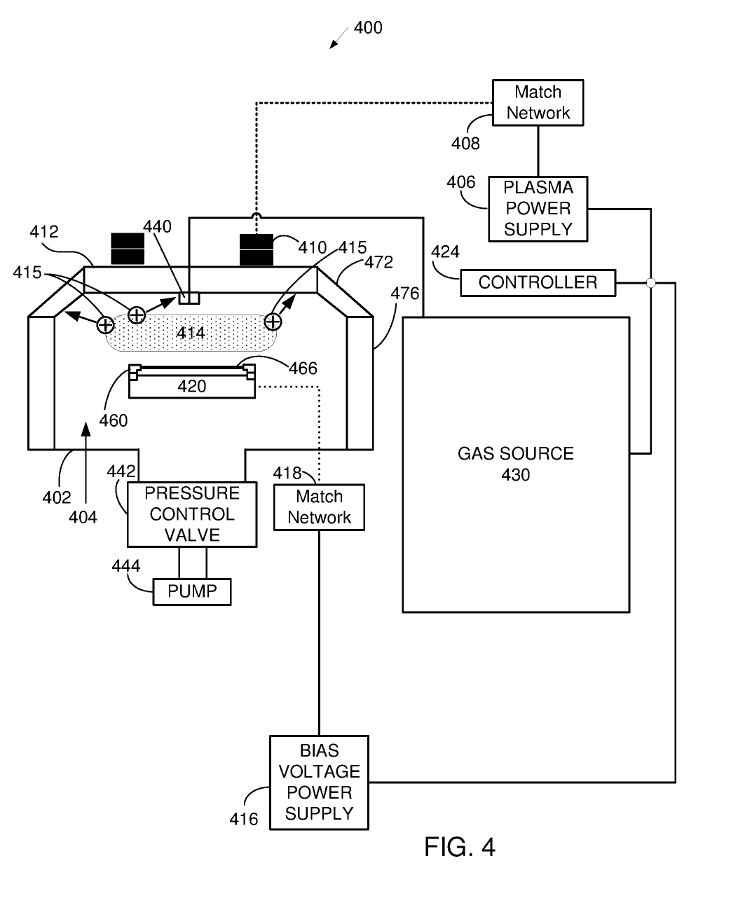

FIG. 4 schematically illustrates an example of another plasma processing chamber 400 which may be used in another embodiment. The plasma processing chamber 400 includes a plasma reactor 402 having a plasma processing confinement chamber 404 therein. A plasma power supply 406, tuned by a match network 408, supplies power to a TCP coil 410 located near a power window 412 to create a plasma 414 in the plasma processing confinement chamber 404 by providing an inductively coupled power. A pinnacle 472 extends from the chamber wall 476 of the confinement chamber 404 to the window 412 forming a pinnacle ring. The pinnacle 472 is angled with respect to the chamber wall 476 and the window 412, such that the interior angle between the pinnacle 472 and the chamber wall 476 and the interior angle between the pinnacle 472 and the window 412 are each greater than 90° and less than 180°. The pinnacle 472 provides an angled ring near the top of the confinement chamber 404, as shown. The TCP coil (upper power source) 410 may be configured to produce a uniform diffusion profile within the plasma processing confinement chamber 404. For example, the TCP coil 410 may be configured to generate a toroidal power distribution in the plasma 414. The power window 412 is provided to separate the TCP coil 410 from the plasma processing confinement chamber 404 while allowing energy to pass from the TCP coil 410 to the plasma processing confinement chamber 404. A wafer bias voltage power supply 416 tuned by a match network 418 provides power to an electrode 420 to set the bias voltage on the substrate 466 which is supported by the electrode 420. A controller 424 sets points for the plasma power supply 406, gas source/gas supply mechanism 430, and the wafer bias voltage power supply 416.

The plasma power supply 406 and the wafer bias voltage power supply 416 may be configured to operate at specific radio frequencies such as, for example, 13.56 MHz, 27 MHz, 2 MHz, 60 MHz, 400 kHz, 2.54 GHz, or combinations thereof. Plasma power supply 406 and wafer bias voltage power supply 416 may be appropriately sized to supply a range of powers in order to achieve desired process performance. For example, in one embodiment, the plasma power supply 406 may supply the power in a range of 50 to 5000 Watts, and the wafer bias voltage power supply 416 may supply a bias voltage of in a range of 20 to 2000 V. In addition, the TCP coil 410 and/or the electrode 420 may be comprised of two or more sub-coils or sub-electrodes, which may be powered by a single power supply or powered by multiple power supplies.

As shown in FIG. 4, the plasma processing chamber 308 further includes a gas source/gas supply mechanism 430. The gas source 430 is in fluid connection with plasma processing confinement chamber 404 through a gas inlet, such as a gas injector 440. The gas injector 440 may be located in any advantageous location in the plasma processing confinement chamber 404, and may take any form for injecting gas. Preferably, however, the gas inlet may be configured to produce a “tunable” gas injection profile, which allows independent adjustment of the respective flow of the gases to multiple zones in the plasma process confinement chamber 404. More preferably, the gas injector is mounted to the power window 412, which means the gas injector may be mounted on, mounted in, or form part of the power window. The process gases and byproducts are removed from the plasma process confinement chamber 404 via a pressure control valve 442 and a pump 444, which also serve to maintain a particular pressure within the plasma processing confinement chamber 404. The pressure control valve 442 can maintain a pressure of less than 1 ton during processing. An edge ring 460 is placed around the substrate 466. The gas source/gas supply mechanism 430 is controlled by the controller 424. A Kiyo by Lam Research Corp. of Fremont, Calif., may be used to practice an embodiment.

FIG. 5 is an enlarged cross-sectional view of the power window 412. The power window 412 comprises a window body 504 and a coating 508 covering at least one surface of the window body 504. In this example, the coating 508 is only on one surface of the window body 504. The window body 504 may be of one or more different materials. Preferably, the window body 504 is ceramic or quartz. More preferably, the window body 504 comprises at least one of silicon (Si), quartz, silicon carbide (SiC), silicon nitride (SiN), aluminum oxide (AlO), aluminum nitride (AlC), or aluminum carbide (AlC). Most preferably, the window body 504 comprises AlO or quartz. The coating 508 comprises at least one of erbium oxide, erbium fluoride, samarium oxide, samarium fluoride, thulium oxide thulium fluoride, gadolinium oxide, or gadolinium fluoride. Therefore, the coating may be a one or more in combination of erbium oxide, erbium fluoride, samarium oxide, samarium fluoride, thulium oxide thulium fluoride, gadolinium oxide, or gadolinium fluoride and may also have other materials. Such other materials may be impurities which are difficult to remove in obtaining erbium oxide, erbium fluoride, samarium oxide, samarium fluoride, thulium oxide thulium fluoride, gadolinium oxide, or gadolinium fluoride or may be binding agents to allow the binding of the coating to the window body. More preferably, the coating is >60% pure by weight of at least one of erbium oxide, erbium fluoride, samarium oxide, samarium fluoride, thulium oxide thulium fluoride, gadolinium oxide, or gadolinium fluoride. Most preferably, the coating is >99% pure by weight of at least one of erbium oxide, erbium fluoride, samarium oxide, samarium fluoride, thulium oxide thulium fluoride, gadolinium oxide, or gadolinium fluoride. Preferably, the coating is 1-50 μ thick. More preferably, the coating is 5-20 μ thick. Most preferably, the coating is 8-15 μ thick. To provide such a uniform and thin coating, preferably the coating is formed by at least one of plasma-enhanced chemical vapor deposition (PECVD), physical vapor deposition (PVD), chemical vapor deposition (CVD), atomic layer deposition (ALD), or aerosol deposition (ASD). Preferably, the coating 508 is only on the side of the window body 504 facing the plasma as shown.

FIG. 6 is an enlarged cross-sectional view of the gas injector 440. The gas injector 440 comprises an injector body 604 and a coating 608 covering at least one surface of the injector body 604. In this example, the coating 608 is only on at least two surfaces of the injector body 604. The injector body 604 has a bore hole 612, through which the gas flows. In some embodiments, the coating 608 may line the bore hole 612. The gas injector 440 may also have a mount 616 for fixing the gas injector 440 to the power window 412. The injector body 604 may be of one or more different materials. Preferably, the injector body 604 is ceramic or quartz. More preferably, the injector body 604 comprises at least one of silicon (Si), quartz, silicon carbide (SiC), silicon nitride (SiN), aluminum oxide (AlO), aluminum nitride (AlC), or aluminum carbide (AlC). Most preferably, the injector body 604 comprises quartz or silicon oxide. The coating 608 comprises at least one of erbium oxide, erbium fluoride, samarium oxide, samarium fluoride, thulium oxide thulium fluoride, gadolinium oxide, or gadolinium fluoride. Therefore, the coating may be a one or more in combination of erbium oxide, erbium fluoride, samarium oxide, samarium fluoride, thulium oxide thulium fluoride, gadolinium oxide, or gadolinium fluoride and may also have other materials. Such other materials may be impurities which are difficult to remove in obtaining erbium oxide, erbium fluoride, samarium oxide, samarium fluoride, thulium oxide thulium fluoride, gadolinium oxide, or gadolinium fluoride or may be binding agents to allow the binding of the coating to the injector body. More preferably, the coating is >60% pure by weight of at least one of erbium oxide, erbium fluoride, samarium oxide, samarium fluoride, thulium oxide thulium fluoride, gadolinium oxide, or gadolinium fluoride. Most preferably, the coating is >99% pure by weight of at least one of erbium oxide, erbium fluoride, samarium oxide, samarium fluoride, thulium oxide thulium fluoride, gadolinium oxide, or gadolinium fluoride. Preferably, the coating is 1-50 μ thick. More preferably, the coating is 5-20 μ thick. Most preferably, the coating is 8-15 μ thick. To provide such a uniform and thin coating, preferably the coating is formed by at least one of plasma-enhanced chemical vapor deposition (PECVD), physical vapor deposition (PVD), chemical vapor deposition (CVD), atomic layer deposition (ALD), or aerosol deposition (ASD).

FIG. 7 is an enlarged cross-sectional view of part of the edge ring 460. The edge ring 460 comprises a ring body 704 and a coating 708 covering at least one surface of the ring body 704. Preferably, the ring body 704 is ceramic, stainless steel, or quartz. More preferably, the lower electrode body 304 comprises at least one of stainless steel, silicon (Si), quartz, silicon carbide (SiC), silicon nitride (SiN), aluminum oxide (AlO), aluminum nitride (AlC), or aluminum carbide (AlC). The coating 708 comprises at least one of erbium oxide, erbium fluoride, samarium oxide, samarium fluoride, thulium oxide thulium fluoride, gadolinium oxide, or gadolinium fluoride. Therefore, the coating may be a one or more in combination of erbium oxide, erbium fluoride, samarium oxide, samarium fluoride, thulium oxide thulium fluoride, gadolinium oxide, or gadolinium fluoride and may also have other materials. Such other materials may be impurities which are difficult to remove in obtaining erbium oxide, erbium fluoride, samarium oxide, samarium fluoride, thulium oxide thulium fluoride, gadolinium oxide, or gadolinium fluoride or may be binding agents to allow the binding of the coating to the electrode body. More preferably, the coating is >60% pure by weight of at least one of erbium oxide, erbium fluoride, samarium oxide, samarium fluoride, thulium oxide thulium fluoride, gadolinium oxide, or gadolinium fluoride. Most preferably, the coating is >99% pure by weight of at least one of erbium oxide, erbium fluoride, samarium oxide, samarium fluoride, thulium oxide thulium fluoride, gadolinium oxide, or gadolinium fluoride. Preferably, the coating is 1-50 μ thick. More preferably, the coating is 5-20 μ thick. Most preferably, the coating is 8-15 μ thick. To provide such a uniform and thin coating, preferably the coating is formed by at least one of plasma-enhanced chemical vapor deposition (PECVD), physical vapor deposition (PVD), chemical vapor deposition (CVD), atomic layer deposition (ALD), or aerosol deposition (ASD).

FIG. 8 is an enlarged cross-sectional view of part of the pinnacle 472. The pinnacle comprises a pinnacle body 804 and a coating 808 covering at least one surface of the pinnacle body 804, which will face into the chamber to be exposed to plasma. Preferably, the pinnacle body 804 is ceramic, stainless steel, or quartz. More preferably, pinnacle body 804 comprises at least one of stainless steel, silicon (Si), quartz, silicon carbide (SiC), silicon nitride (SiN), aluminum oxide (AlO), aluminum nitride (AlC), or aluminum carbide (AlC). The coating 808 comprises at least one of erbium oxide, erbium fluoride, samarium oxide, samarium fluoride, thulium oxide thulium fluoride, gadolinium oxide, or gadolinium fluoride. Therefore, the coating may be a one or more in combination of erbium oxide, erbium fluoride, samarium oxide, samarium fluoride, thulium oxide thulium fluoride, gadolinium oxide, or gadolinium fluoride and may also have other materials. Such other materials may be impurities which are difficult to remove in obtaining erbium oxide, erbium fluoride, samarium oxide, samarium fluoride, thulium oxide thulium fluoride, gadolinium oxide, or gadolinium fluoride or may be binding agents to allow the binding of the coating to the electrode body. More preferably, the coating is >60% pure by weight of at least one of erbium oxide, erbium fluoride, samarium oxide, samarium fluoride, thulium oxide thulium fluoride, gadolinium oxide, or gadolinium fluoride. Most preferably, the coating is >99% pure by weight of at least one of erbium oxide, erbium fluoride, samarium oxide, samarium fluoride, thulium oxide thulium fluoride, gadolinium oxide, or gadolinium fluoride. Preferably, the coating is 1-50 μ thick. More preferably, the coating is 5-20 μ thick. Most preferably, the coating is 8-15 μ thick. To provide such a uniform and thin coating, preferably the coating is formed by at least one of plasma-enhanced chemical vapor deposition (PECVD), physical vapor deposition (PVD), chemical vapor deposition (CVD), atomic layer deposition (ALD), or aerosol deposition (ASD).

It has been unexpectedly found that coatings comprising at least one of erbium oxide, erbium fluoride, samarium oxide, samarium fluoride, thulium oxide thulium fluoride, gadolinium oxide, or gadolinium fluoride are highly etch resistant. It has been found that PVD, CVD, ALD, or ASD may provide a thin but uniform layer that is highly etch resistant. Such a thin layer is easy to apply without significantly changing the dimensions of the object.

In inductively coupled plasma reactors, one of the highest erosion mechanisms of parts is due to ion sputtering. Most sputtering is done by high energy ions, which bombard the power window 412, pinnacle 472, and gas injector 440 according to the geometry of the chamber. These high energy ions are energized through a RF field attacking the powered ends (coil and ESC) of the chamber. Hence these parts need extra protection. This is illustrated in FIG. 4 showing various positive ions 415 colliding with the pinnacle 472, power window 412, or gas injector 440.

In other embodiments, other components such as the confinement rings 102, chamber walls 152, or upper electrode 104 may also have an etch resistant coating.

While this disclosure has been described in terms of several embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

What is claimed is:

1. An apparatus for processing a substrate, comprising
a chamber wall forming processing chamber cavity;
a substrate support for supporting the substrate within the processing chamber cavity;
a window for passing RF power into the processing chamber cavity, comprising:
a ceramic or quartz window body; and
a coating on a surface of the window body facing the processing chamber cavity comprising at least one of erbium oxide, erbium fluoride, samarium oxide, samarium fluoride, thulium oxide thulium fluoride, gadolinium oxide, or gadolinium fluoride on at least one surface of the window body; and
a coil outside of the processing chamber cavity, wherein the window is between the processing chamber cavity and the coil.

2. The apparatus, as recited in claim 1, wherein the coating of at least one of erbium oxide, erbium fluoride, samarium oxide, samarium fluoride, thulium oxide thulium fluoride, gadolinium oxide, or gadolinium fluoride on a surface of the window body is formed by at least one of plasma-enhanced chemical vapor deposition, physical vapor deposition, chemical vapor deposition, atomic layer deposition, or aerosol deposition.

3. The apparatus, as recited in claim 2, wherein the coating of at least one of erbium oxide, erbium fluoride, samarium oxide, samarium fluoride, thulium oxide thulium fluoride, gadolinium oxide, or gadolinium fluoride on a surface of the window body is 1 to 50 microns thick.

4. The apparatus, as recited in claim 3, wherein the window body comprises at least one of quartz or aluminum oxide.

5. The apparatus, as recited in claim 4, wherein the coating is greater than 60% pure.

6. The apparatus, as recited in claim 1, further comprising:
a pinnacle ring extending from the chamber wall to the window, wherein the pinnacle is angled with respect to the chamber wall and the window and wherein the pinnacle, comprises:
a pinnacle body; and
a coating comprising at least one of erbium oxide, erbium fluoride, samarium oxide, samarium fluoride, thulium oxide thulium fluoride, gadolinium oxide, or gadolinium fluoride, covering at least one surface of the pinnacle body.

7. The apparatus, as recited in claim 6, further comprising a gas inlet for providing gas into the processing chamber through the window, wherein the gas inlet, comprises:
an inlet body; and
a coating comprising at least one of erbium oxide, erbium fluoride, samarium oxide, samarium fluoride, thulium oxide thulium fluoride, gadolinium oxide, or gadolinium fluoride, covering at least one surface of the inlet body

8. The apparatus, as recited in claim 1, wherein the coating of at least one of erbium oxide, erbium fluoride, samarium oxide, samarium fluoride, thulium oxide thulium fluoride, gadolinium oxide, or gadolinium fluoride covering a surface of the window body is formed by at least one of plasma-enhanced chemical vapor deposition or physical vapor deposition.

9. An apparatus for plasma processing a substrate, comprising a chamber wall forming processing chamber cavity;
a substrate support for supporting the substrate within the processing chamber cavity;
a gas inlet for providing a gas into the processing chamber cavity;
at least one plasma electrode for transforming a gas within the processing chamber cavity into a plasma; and
a coating comprising at least one of erbium oxide, erbium fluoride, samarium oxide, samarium fluoride, thulium oxide thulium fluoride, gadolinium oxide, or gadolinium fluoride, is on a surface within the processing chamber cavity, wherein the coating is 1 to 50 microns thick.

10. The apparatus, as recited in claim 9, wherein the plasma processing chamber further comprises:
a power window, which separates the at least one plasma electrode from the processing chamber cavity;
a pinnacle extending from the chamber wall to the power window, wherein the gas inlet extends through the power window, and wherein the coating coats a surface of at least one of the power window, pinnacle or gas inlet.

11. The apparatus, as recited in claim 9, wherein the coating of at least one of erbium oxide, erbium fluoride, samarium oxide, samarium fluoride, thulium oxide thulium fluoride, gadolinium oxide, or gadolinium fluoride covering a surface of the window body is formed by at least one of plasma-enhanced chemical vapor deposition, physical vapor deposition, chemical vapor deposition, atomic layer deposition, or aerosol deposition.

12. The apparatus, as recited in claim 9, further comprising a liner, wherein the coating coats the liner.

13. The apparatus, as recited in claim 9, wherein the coating of at least one of erbium oxide, erbium fluoride, samarium oxide, samarium fluoride, thulium oxide thulium fluoride, gadolinium oxide, or gadolinium fluoride covering a surface of the window body is formed by at least one of plasma-enhanced chemical vapor deposition or physical vapor deposition.

14. The apparatus, as recited in claim 9, further comprising an edge ring, wherein the coating coats the edge ring.

15. An apparatus for use in a plasma etch chamber, comprising:
a body; and
a coating comprising at least one of erbium oxide, erbium fluoride, samarium oxide, samarium fluoride, thulium oxide thulium fluoride, gadolinium oxide, or gadolinium fluoride covering a surface of the body, wherein the coating is 1 to 50 microns thick.

16. The apparatus, as recited in claim 15, wherein the body comprises at least one of Si, quartz, SiC, SiN, aluminum oxide, aluminum nitride, stainless steel, or aluminum carbide.

17. The apparatus, as recited in claim 16, wherein the coating is formed by at least one of physical vapor deposition, chemical vapor deposition, atomic layer deposition, or aerosol deposition.

18. The apparatus, as recited in claim 16, wherein the coating is greater than 99% pure.
